(19) United States
(12) Patent Application Publication
(10) Pub. No.: US 2025/0131961 A1
(43) Pub. Date: Apr. 24, 2025

(54) SEMICONDUCTOR DEVICE

(71) Applicant: SK hynix Inc., Gyeonggi-do (KR)

(72) Inventors: Won Jae CHOI, Gyeonggi-do (KR); Sung Lae OH, Gyeonggi-do (KR)

(21) Appl. No.: 18/419,557

(22) Filed: Jan. 23, 2024

(30) Foreign Application Priority Data
Oct. 23, 2023 (KR) 10-2023-0141815

(51) Int. Cl. G11C 16/04; G11C 5/06; G11C 16/24; H01L 25/065; H10B 41/27; H10B 43/27; H10B 80/00

(52) U.S. Cl. CPC G11C 16/0483; G11C 5/063; G11C 16/24; H01L 25/0657; H10B 41/27; H10B 43/27; H10B 80/00; H01L 2225/06513

(57) ABSTRACT

A semiconductor device may include a first memory block including at least one first string that is connected between at least one first bit line and a first common source line, a second memory block including at least one second string that is connected between at least one second bit line and a second common source line, and a bit line connection circuit connected between the first bit line and the second bit line and configured to electrically connect or separate the first bit line and the second bit line.

### CROSS-REFERENCE TO RELATED APPLICATION

This application claims priority under 35 U.S.C. § 119 to Korean Patent Application No. 10-2023-0141815 filed on Oct. 23, 2023, which is incorporated herein by reference in its entirety.

### BACKGROUND

### 1. Technical Field

Embodiments of the present disclosure relate to three dimensional integrated circuit technology and, more particularly, to a three dimensional semiconductor device technology.

### 2. Related Art

Recently, as consumer demand for smaller size, lower power consumption, and high performance electronic devices continues to increase, further improvements are needed in semiconductor device technology for providing semiconductor devices which are capable of storing information and satisfy these needs for various electronic devices, such as computers and portable communication devices.

Reducing the size of a semiconductor device and increasing its data storage capacity, has become increasingly more difficult and expensive for two dimensional (2D) semiconductor devices because integrating more memory cells in the same 2D area requires reducing the width of the metal lines to levels that have become very difficult to obtain. Generally, further reduction in the width of the metal lines requires addressing difficult problems with the manufacturing equipment, very high investment costs, and very long development periods.

As a result, semiconductor devices with three-dimensional structures have been proposed and are currently actively researched and developed.

### SUMMARY

Embodiments of the present disclosure provide an improved 3D-semiconductor device (hereinafter referred to simply as semiconductor device).

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected.

Thus, the described embodiments should not be construed as being limited to the particular configurations and shapes illustrated herein but may include deviations in configurations and shapes which do not depart from the spirit and scope of the present disclosure as defined in the appended claims.

The present invention is described herein with reference to cross-section and/or plan illustrations of embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present disclosure.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly on the second layer or the substrate.

It should be understood that the drawings are simplified schematic illustrations of the described devices and may not include well known details for avoiding obscuring the features of the invention.

It should also be noted that features present in one embodiment may be used with one or more features of another embodiment without departing from the scope of the disclosure.

It is further noted, that in the various drawings, like reference numbers designate like elements.

Hereinbelow, in the accompanying drawings, a direction perpendicular to the top surface of a substrate is defined as a third direction III, and two directions parallel to the top surface of the substrate and intersecting with each other are defined as a first and a second direction I and II, respectively. The substrate may correspond to a single layer or a multi-layer substrate. The second direction II may correspond to the extending direction of word lines, and the first direction I may correspond to the extending direction of bit lines. The first and second directions I and II may intersect substantially perpendicularly with each other. In the drawings, a direction indicated by an arrow and a direction opposite thereto represent the same direction.

The terminology used herein is for the purpose of describing particular embodiments only and is not intended to be limiting of the scope of the present disclosure.

As used herein, singular forms are intended to include the plural forms as well, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure.

It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

According to an embodiment of the present disclosure, a semiconductor device is provided, the semiconductor device including a first memory block including at least one first string that is connected between at least one first bit line and a first common source line, a second memory block including at least one second string that is connected between at least one second bit line and a second common source line, and a bit line connection circuit connected between the first bit line and the second bit line and configured to electrically connect or separate the first bit line and the second bit line.

In an embodiment of the present disclosure, a semiconductor device may include a first memory device including at least one first string that is connected between at least one first bit line and a first common source line and a second memory device including at least one second string that is connected between at least one second bit line and a second common source line. One of the first and second memory devices may include a bit line connection circuit configured to electrically connect or separate the first bit line and the second bit line.

These and other features and advantages of the embodiments of the present disclosure will become apparent to those skilled in the art from the following detailed description and drawings.

### BRIEF DESCRIPTION OF THE DRAWINGS

FIGS. 1A and 1B are diagrams describing a semiconductor device according to an embodiment of the present disclosure.

FIGS. 2A and 2B are diagrams describing a semiconductor device according to another embodiment of the present disclosure.

FIGS. 3A and 3B are diagrams describing a semiconductor device according to still another embodiment of the present disclosure.

FIGS. 4 and 5 are diagrams describing a semiconductor device according to yet another embodiment of the present disclosure.

### DETAILED DESCRIPTION

Hereinafter, embodiments according to the technical concepts of the present disclosure are described with reference to the accompanying drawings.

Embodiments of the present disclosure provide a semiconductor device capable of adjusting its data storage capacity or data processing speed, if necessary.

Performance of a semiconductor device can be adjusted, if necessary, by increasing the data storage capacity of the semiconductor device or improving the data processing speed of the semiconductor device.

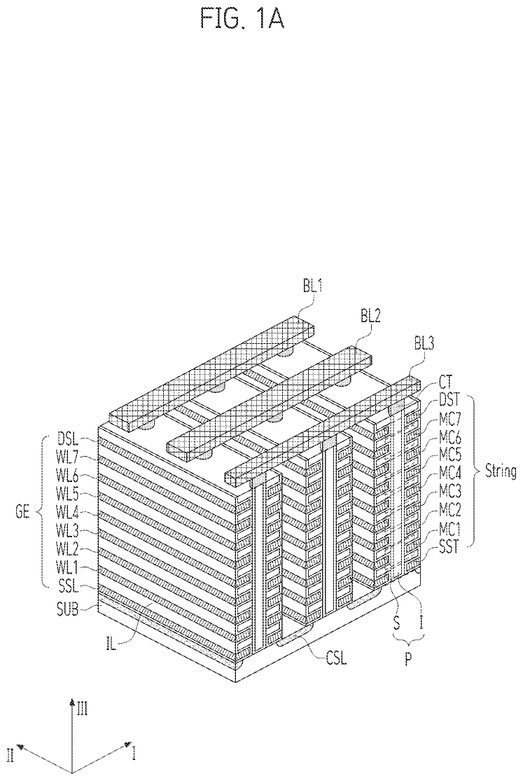

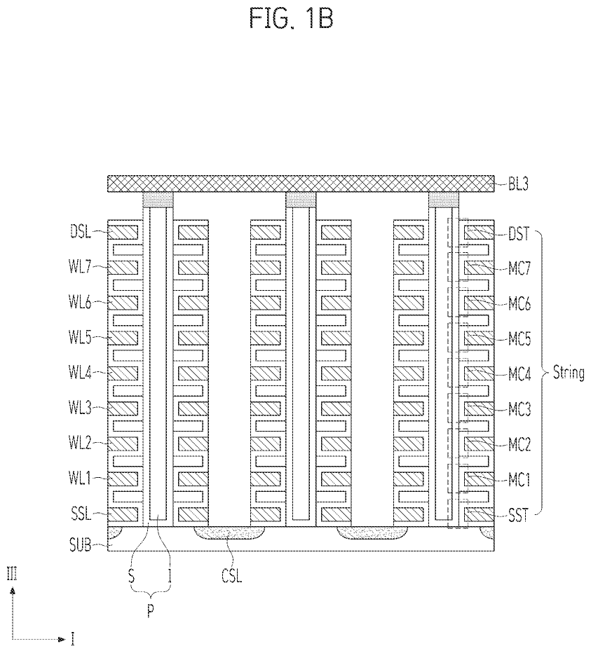

FIGS. 1A and 1B are diagrams describing a semiconductor device according to an embodiment of the present disclosure.

FIG. 1A is a perspective view illustrating a memory block of the semiconductor device. Furthermore, FIG. 1B is a cross-sectional view illustrating a plane defined in a first direction I and a third direction III in FIG. 1A. The third direction III is a direction perpendicular to a plane that is defined in the first direction I and a second direction II.

Referring to FIGS. 1A and 1B, a memory block is illustrated including two selection lines DSL and SSL, seven word lines WL1 to WL7, and three bit lines BL1, BL2, and BL3, but this is merely for convenience of description and the present disclosure is not limited thereto.

The memory block may be formed over a substrate SUB. The memory block may be formed in a direction (e.g., the third direction III) that is perpendicular to the substrate SUB. The substrate SUB may be a polysilicon layer that has been doped to have a first conductive type (e.g., a P type). The substrate SUB may be made of a semiconductor material, such as, for example, at least one of silicon (Si), germanium (Ge), silicon germanium (SiGe), gallium arsenic (GaAs), indium gallium arsenic (AlGaAs), or any combination thereof.

A common source line CSL that extends in the second direction II may be formed on the substrate SUB. The common source line CSL may be doped with impurities of a second conductive type (e.g., an N type impurity).

A plurality of insulating layers IL and a plurality of gate electrodes GE may be alternately stacked on the substrate SUB in the third direction III. Furthermore, the plurality of gate electrodes GE may be formed to extend in the second direction II. The gate electrodes GE correspond to the word lines WL1 to WL7 and the selection lines DSL and SSL. The insulating layers IL and the gate electrodes GE may be stacked over the substrate SUB in an alternating manner with one insulating layer IL between every two consecutive gate electrodes GE. Hence, the plurality of gate electrodes GE may include the source selection line SSL, the plurality of word lines WL1 to WL7, and the drain selection line DSL.

A plurality of pillars P may be formed to extend in the third direction III through the plurality of insulating layers IL and the plurality of gate electrodes GE. Each of the plurality of pillars P may be formed to be connected to the substrate SUB. The plurality of pillars P may each include a surface layer S and an internal layer I formed within the surface layer S. The surface layer S of each pillar P may be formed to surround the internal layer I. The surface layer S of each pillar P may include a silicon material doped with a first conductive type impurity. The surface layer S may function as a channel region. For example, the surface layer S of each pillar P may include a channel layer and a memory layer. The channel layer may include a semiconductor layer having a polycrystalline state, and an embodiment may include a polycrystalline silicon layer. The memory layer may be formed to surround the channel layer. The memory layer may include a blocking layer, a charge trap layer, and a tunnel insulating layer. The tunnel insulating layer may be formed to surround the channel layer. The charge trap layer may be formed to surround the tunnel insulating layer. Furthermore, the blocking layer may be formed to surround the charge trap layer. The tunnel insulating layer may include an oxide layer. The charge trap layer may include a nitride layer. The blocking layer may include an oxide layer. The pillar P may also be referred to as a vertical channel structure. The internal layer I of each pillar P may include an insulating material, such as silicon oxide, or an air gap. Furthermore, the size of a channel hole in each pillar P may be reduced toward the substrate SUB. A plurality of contacts CT may be formed between each pillar P and the bit lines BL1, BL2, and BL3, and may electrically connect the bit lines and a string. For example, the plurality of contacts CT may electrically connect the internal layer I that serves as a channel function of each pillar P and each of the bit lines BL1, BL2, BL3.

The string may be electrically connected between each of the plurality of bit lines BL1, BL2, and BL3 and each common source line CSL. The string may include the memory layer and the channel layer that are included in the internal layer I of the pillar P and a plurality of transistors connected in series with each transistor including a gate electrode GE. For example, a transistor that is electrically connected to the common source line CSL, among the plurality of transistors that are connected in series, may be referred to as a source selection transistor SST. Furthermore, a transistor that is connected to each of the bit lines BL1, BL2, and BL3, among the plurality of transistors that are connected in series, may be referred to as a drain selection transistor DST. The remaining transistors of the plurality of transistors except the source selection transistor SST and the drain selection transistor DST may be referred to as cell transistors. In FIGS. 1A and 1B according to an embodiment of the present disclosure, the seven word lines WL1 to WL7 have been illustrated. Accordingly, the remaining transistors that are the cell transistors may also be referred to as the seven memory cells MC1 to MC7. That is, the source selection transistor SST refers to a transistor having a gate connected to the source selection line SSL. The drain selection transistor DST refers to a transistor having a gate connected to the drain selection line DSL. The memory cell, that is, the cell transistor, means a transistor having a gate connected to the word line.

Accordingly, the semiconductor device according to an embodiment of the present disclosure may include a plurality of strings, each string including a plurality of memory cells connected in series between a plurality of the bit lines and the common source line.

The semiconductor device constructed as described above according to an embodiment of the present disclosure can control a string that is connected to a selected bit line by selecting at least one of a plurality of bit lines. The plurality of memory cells MC1 to MC7 that are included in the string that is connected to the selected bit line may each perform program, erase, and read operations through control of the plurality of word lines WL1 to WL7.

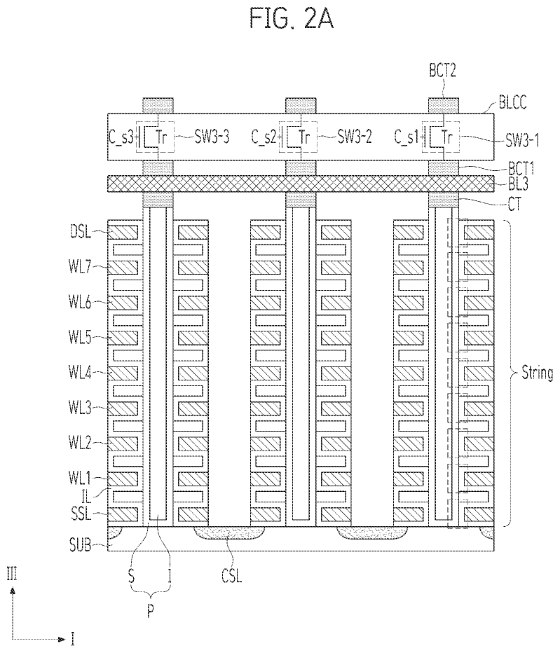

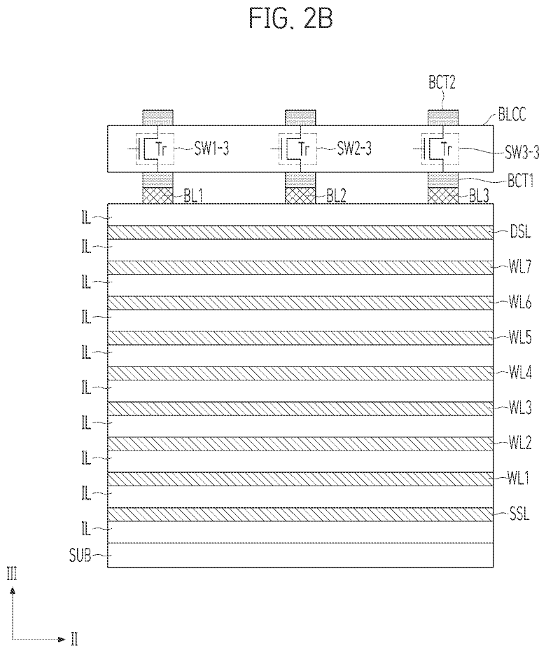

FIGS. 2A and 2B are diagrams describing a semiconductor device according to another embodiment of the present disclosure.

Referring to FIGS. 2A and 2B, the semiconductor device according to another embodiment of the present disclosure may further include a bit line connection circuit BLCC in addition to the semiconductor device illustrated in FIGS. 1A and 1B. For example, a description of components redundant with the components illustrated in FIGS. 1A and 1B will be omitted.

The bit line connection circuit BLCC may be formed over the plurality of bit lines BL1, BL2, and BL3. The plurality of bit lines BL1, BL2, and BL3 may be electrically connected to the bit line connection circuit BLCC through a plurality of first bit line contacts BCT1. Furthermore, a plurality of second bit line contacts BCT2 may be formed on the bit line connection circuit BLCC.

The bit line connection circuit BLCC may include a plurality of switches SW that electrically connect or separate the plurality of first bit line contacts BCT1 and the plurality of second bit line contacts BCT2.

For example, referring to FIG. 2A, the plurality of first bit line contacts BCT1 may be formed between one bit line BL3 and the bit line connection circuit BLCC. That is, the plurality of first bit line contacts BCT1 may be formed under the bit line connection circuit BLCC. Furthermore, the plurality of second bit line contacts BCT2 may be formed over the bit line connection circuit BLCC. For example, the bit line connection circuit BLCC may include a plurality of switches SW3-1, SW3-2, and SW3-3 that electrically connect or separate the plurality of first bit line contacts BCT1 and the plurality of second bit line contacts BCT2.

Furthermore, referring to FIG. 2B, the plurality of first bit line contacts BCT1 may be formed between the plurality of bit lines BL1, BL2, and BL3 and the bit line connection circuit BLCC. As described above, the plurality of first bit line contacts BCT1 may be formed under the bit line connection circuit BLCC, and the plurality of second bit line contacts BCT2 may be formed over the bit line connection circuit BLCC.

The bit line connection circuit BLCC may include at least one of the switches SW1-3, SW2-3, and SW3-3 that connect or separate the first bit line contacts BCT1 and the second bit line contacts BCT2, respectively, which are connected to the bit lines BL1, BL2, and BL3.

In FIG. 2A, the bit line connection circuit BLCC has been illustrated as including the three switches SW3-1, SW3-2, and SW3-3 that are connected to one bit line BL3. In FIG. 2B, the bit line connection circuit BLCC has been illustrated as including the switches SW1-3, SW2-3, and SW3-3 that are connected to the three bit lines BL1, BL2, and BL3, respectively. Accordingly, three switches are connected to one bit line, a total number of switches that are connected to the three bit lines is 9. Hence, according to the illustrated embodiment, the bit line connection circuit BLCC may include nine switches. However, it should be understood, that the above description is merely an example according to an embodiment, and the embodiments of the present disclosure are not limited thereto.

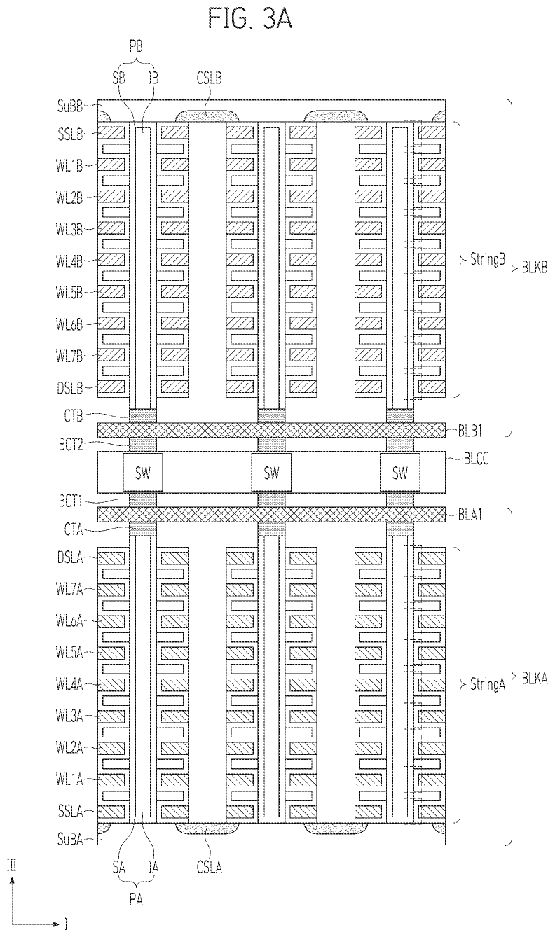

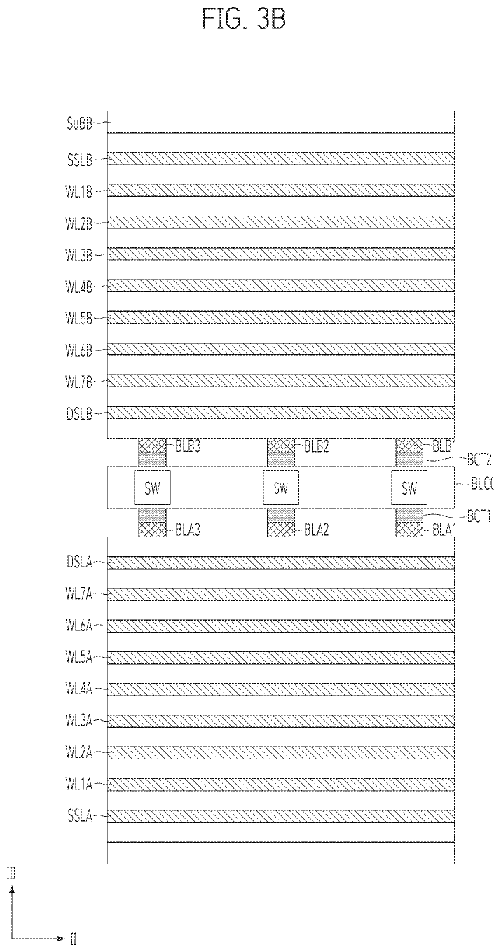

FIGS. 3A and 3B are diagrams describing a semiconductor device according to still another embodiment of the present disclosure.

Referring to FIGS. 3A and 3B, in the semiconductor device, a first memory block BLKA may be formed on a lower side of a bit line connection circuit BLCC, and a second memory block BLKB may be formed on an upper side of the bit line connection circuit BLCC.

The first memory block BLKA may include at least one first string StringA that is controlled by a first source selection line SSLA, a plurality of first word lines WL1A to WL7A, and the first drain selection line DSLA. For example, the at least one first string StringA may be connected between a first common source line CSLA and a first bit line BLA1. The first memory block BLKA may include a plurality of first bit lines BLA1, BLA2, and BLA3. For example, the at least one first string StringA may be connected between each of the plurality of first bit lines BLA1, BLA2, and BLA3 and the common source line CSLA.

The second memory block BLKB may include at least one second string StringB that is controlled by a second source selection line SSLB, a plurality of first word lines WL1B to WL7B, and a second drain selection line DSLB. For example, the at least one second string StringB may be connected between a second common source line CSLB and a second bit line BLB1. The second memory block BLKB may include a plurality of second bit lines BLB1, BLB2, and BLB3. For example, the at least one second string StringB may be connected between each of the plurality of second bit lines BLB1, BLB2, and BLB3 and the common source line CSLB.

A plurality of first bit line contacts BCT1 may be connected between the bit line connection circuit BLCC and the plurality of first bit lines BLA1, BLA2, and BLA3. Furthermore, a plurality of second bit line contacts BCT2 may be connected between the bit line connection circuit BLCC and the plurality of second bit lines BLB1, BLB2, and BLB3.

The bit line connection circuit BLCC may include at least one switch SW that electrically connects or separates each of the plurality of first bit lines BLA1, BLA2, and BLA3 and each of the plurality of second bit lines BLB1, BLB2, and BLB3. A detailed description of the construction of the bit line connection circuit BLCC will be substituted with that of FIGS. 2A and 2B.

The semiconductor device constructed as described above according to still another embodiment of the present disclosure can electrically connect or separate the at least one first string StringA of the first memory block BLKA and the at least one second string StringB of the second memory block BLKB through the bit line connection circuit BLCC. That is, when the first and second strings StringA and StringB are electrically separated, the semiconductor device may perform an operation, such as a program, erase, or read operation, on memory cells that are connected to one of the first and second strings StringA and StringB. Furthermore, when the first and second strings StringA and StringB are electrically connected, the semiconductor device may perform an operation, such as a program, erase, or read operation, on memory cells that are connected to the first and second strings StringA and StringB.

As a result, the semiconductor device according to still another embodiment of the present disclosure can operate the two memory blocks BLKA and BLKB as one memory block by connecting the bit lines BLA1, BLA2, and BLA3 of the first memory block BLKA and the bit lines BLB1, BLB2, and BLB3 of the second memory block BLKB through the bit line connection circuit BLCC. Accordingly, the data storage capacity of the semiconductor device can be increased.

Furthermore, the semiconductor device according to still another embodiment of the present disclosure is capable of operating at any time only one of the first and second memory blocks BLKA and BLKB by separating the bit lines BLA1, BLA2, and BLA3 of the first memory block BLKA from the bit lines BLB1, BLB2, and BLB3 of the second memory block BLKB via the bit line connection circuit BLCC. The electrical separation of the two memory blocks BLKA and BLKB allows significant increase in the data processing speed of the semiconductor device because of a reduced load in the lines compared to an operation where the two memory blocks BLKA and BLKB are operated together as one memory block.

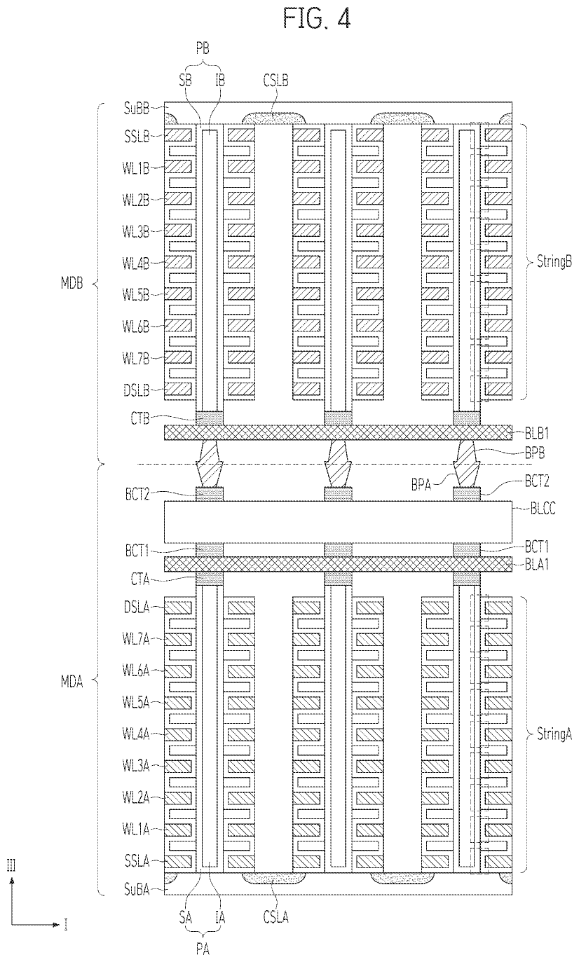

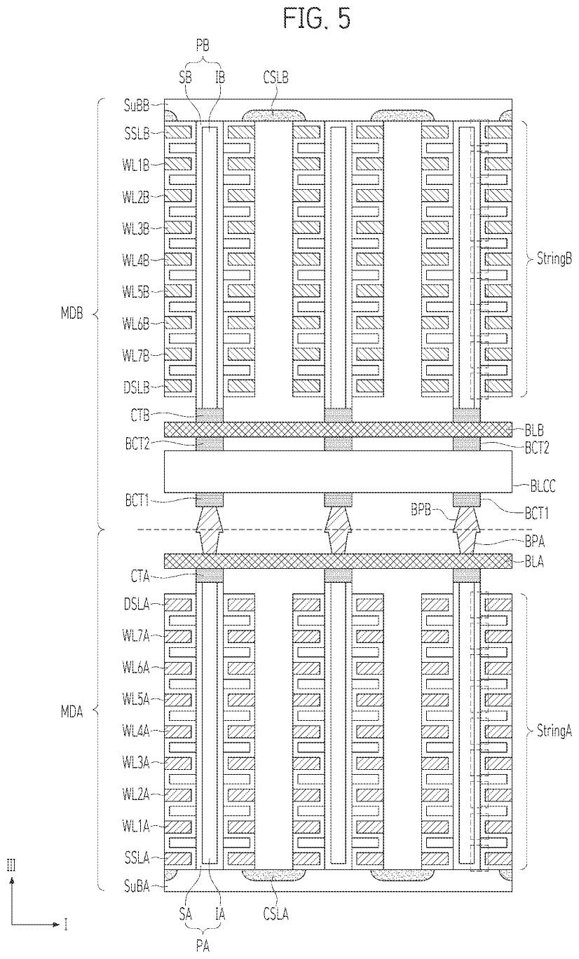

FIGS. 4 and 5 are diagrams describing a semiconductor device according to yet another embodiment of the present disclosure.

FIGS. 4 and 5 illustrate a semiconductor device in which two memory devices MDA and MDB which are formed in different wafers are connected through bonding pads BPA and BPB. For example, one of the two memory devices MDA and MDB may include a bit line connection circuit BLCC.

Referring to FIG. 4, the first memory device MDA may include at least one first bit line BLA1, at least one first string StringA that is connected to the first bit line BLA1, the bit line connection circuit BLCC that is connected to the first bit line BLA1 through at least one first bit line contact BCT1, and at least one first bonding pad BPA that is connected to the bit line connection circuit BLCC through at least one second bit line contact BCT2.

The second memory device MDB may include at least one second bit line BLB1, at least one second string StringB that is connected to the second bit line BLB1, and at least one second bonding pad BPB that is formed on the second bit line BLB1. For example, the first memory device MDA and the second memory device MDB may be memory devices formed in different wafers.

The first memory device MDA and the second memory device MDB may be connected through at least one of the first and second bonding pads BPA and BPB.

The semiconductor device constructed as described above according to yet another embodiment of the present disclosure can electrically connect or separate the at least one first string StringA of the first memory device MDA and the at least one second string StringB of the second memory device MDB through the bit line connection circuit BLCC. That is, when the first and second strings StringA and StringB are electrically separated, the semiconductor device may perform an operation, such as a program, erase, or read operation, on memory cells that are connected to one of the first and second strings StringA and StringB. Furthermore, when the first and second strings StringA and StringB are electrically connected, the semiconductor device may perform an operation, such as a program, erase, or read operation, on memory cells that are connected to the first and second strings StringA and StringB.

As a result, the semiconductor device according to yet another embodiment of the present disclosure can operate the two memory devices MDA and MDB as one memory device by connecting the bit line BLA of the first memory device MDA and the bit line BLB of the second memory device MDB through the bit line connection circuit BLCC. Accordingly, the data storage capacity of the semiconductor device can be increased.

Furthermore, the semiconductor device according to yet another embodiment of the present disclosure can operate only one of the first and second memory devices MDA and MDB by separating the bit line BLA of the first memory device MDA and the bit line BLB of the second memory device MDB through the bit line connection circuit BLCC. Accordingly, the data processing speed of the semiconductor device can be increased by reducing the loading in or between the lines by electrically separating the two memory devices MDA and MDB compared to a case in which the two memory devices MDA and MDB are operated as one memory device.

Referring to FIG. 5, a first memory device MDA may include at least one first bit line BLA, at least one first string StringA that is connected to the first bit line BLA, and at least one first bonding pad BPA that is formed on the first bit line BLA.

The second memory device MDB may include at least one second bit line BLB, at least one second string StringB that is connected to the second bit line BLB, a bit line connection circuit BLCC that is connected to the second bit line BLB through at least one second bit line contact BCT2, and at least one second bonding pad BPB that is connected to the bit line connection circuit BLCC through at least one first bit line contact BCT1. For example, the first and second memory devices MDA and MDB may be memory devices that are formed in different wafers.

The first and second memory devices MDA and MDB may be connected through at least one of the pairs of the first and second bonding pads BPA and BPB.

The semiconductor device constructed as described above according to yet another embodiment of the present disclosure may electrically connect or separate the at least one first string StringA of the first memory device MDA and the at least one second string StringB of the second memory device MDB through the bit line connection circuit BLCC. That is, when the first and second strings StringA and StringB are electrically separated, the semiconductor device may perform an operation, such as a program, erase, or read operation, on memory cells that are connected to one of the first and second strings StringA and StringB. Furthermore, when the first and second strings StringA and StringB are electrically connected, the semiconductor device may perform an operation, such as a program, erase, or read operation, on memory cells that are connected to the first and second strings StringA and StringB.

As a result, the semiconductor device according to yet another embodiment of the present disclosure can operate the two memory devices MDA and MDB as one memory device by connecting the bit line BLA of the first memory device MDA and the bit line BLB of the second memory device MDB through the bit line connection circuit BLCC. Accordingly, the data storage capacity of the semiconductor device can be increased.

Furthermore, the semiconductor device according to yet another embodiment of the present disclosure can operate only one of the first and second memory devices MDA and MDB by separating the bit line BLA of the first memory device MDA and the bit line BLB of the second memory device MDB through the bit line connection circuit BLCC. Accordingly, the data processing speed of the semiconductor device can be increased by reducing the load between lines by electrically separating the two memory devices MDA and MDB compared to a case in which the two memory devices MDA and MDB are operated as one memory device.

Although embodiments according to the technical concepts of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical concepts and scope of the present disclosure as defined in the appended claims. Such substitutions, modifications, and changes may be said to belong to the scope of the present invention disclosure. Therefore, the scope of the present disclosure should not be limited to the above-described embodiments but should include the equivalents thereof.

In the above-described embodiments, all operations may be selectively performed, or part of the operations may be omitted. In each embodiment, the operations are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

The embodiments of the present disclosure have been described in the drawings and specification. Although specific terminologies are used here, those are only to describe the embodiments of the present disclosure. Therefore, the present disclosure is not restricted to the above-described embodiments and many variations are possible within the scope of the present disclosure. It should be apparent to those skilled in the art that various modifications can be made on the basis of the technological scope of the present disclosure in addition to the embodiments disclosed herein. Furthermore, the embodiments may be combined to form additional embodiments.

What is claimed is:

1. A semiconductor device comprising:
a first memory block comprising at least one first string that is connected between at least one first bit line and a first common source line;
a second memory block comprising at least one second string that is connected between at least one second bit line and a second common source line; and
a bit line connection circuit connected between the first bit line and the second bit line and configured to electrically connect or separate the first bit line and the second bit line.

2. The semiconductor device of claim 1, wherein each of the first and second strings comprises a plurality of memory cells.

3. The semiconductor device of claim 1, wherein the bit line connection circuit comprises at least one switch configured to electrically connect or separate the first bit line and the second bit line.

4. The semiconductor device of claim 1, wherein:
the bit line connection circuit is disposed over the first memory block, and
the second memory block is disposed over the bit line connection circuit.

5. A semiconductor device comprising:
a first memory device comprising at least one first string that is connected between at least one first bit line and a first common source line; and
a second memory device comprising at least one second string that is connected between at least one second bit line and a second common source line,
wherein one of the first and second memory devices comprises a bit line connection circuit configured to electrically connect or separate the first bit line and the second bit line.

6. The semiconductor device of claim 5, wherein the first and second strings each comprise a plurality of memory cells.

7. The semiconductor device of claim 1, wherein the bit line connection circuit comprises at least one switch configured to electrically connect or separate the first bit line and the second bit line.

8. The semiconductor device of claim 5, wherein the first and second memory devices are formed in different wafers.

9. The semiconductor device of claim 8, wherein:
the second memory device is disposed over the first memory device, and
the first and second memory devices are connected through at least one bonding pad.

10. A semiconductor device comprising:
a plurality of memory blocks, each memory block comprising at least one string connected between at least one bit line and a first common source line; and
a plurality of bit line connection circuits, each bit line connection circuit configured to electrically connect or isolate at least two of the plurality of memory blocks by electrically connecting the at least one bit line of one memory block with the at least one bit line of another memory block.
